(19) United States
(12) Patent Application Publication
(10) Pub. No.: US 2026/0223566 A1
(43) Pub. Date: Jul. 30, 2026

(54) DISPLAY PANEL AND DISPLAY APPARATUS

(71) Applicant: Wuhan Tianma Microelectronics Co., Ltd., Wuhan (CN)

(72) Inventor: Dan HUANG, Wuhan (CN)

(73) Assignee: Wuhan Tianma Microelectronics Co., Ltd., Wuhan (CN)

(21) Appl. No.: 19/235,514

(22) Filed: Jun. 11, 2025

(30) Foreign Application Priority Data
Jan. 24, 2025 (CN) 202510120822.1

(51) Int. Cl. H10K 59/65; G06V 40/13

(52) U.S. Cl. CPC H10K 59/65; G06V 40/1318

(57) ABSTRACT

The present application discloses a display panel and a display apparatus. The display panel comprises a substrate, a photosensitive element located on a side of the substrate, a first planarization layer located on a side of the photosensitive element away from the substrate, and a light-emission element located on a side of the first planarization layer away from the substrate. In the light-sensing recognition area, the light transmittance of the first planarization layer is greater than or equal to 67%. In the display panel and the display apparatus provided in embodiments of the present application, the photosensitive element is disposed inside the display panel, and the light transmittance of the first planarization layer in the light-sensing recognition area is set to be greater than or equal to 67%.

### CROSS REFERENCE TO RELATED APPLICATION

The present application claims priority to Chinese Patent Application No. 202510120822.1 filed on Jan. 24, 2025, which is incorporated herein by reference in its entirety.

### TECHNICAL FIELD

The present application relates to the technical field of display, and in particular to a display panel and a display apparatus.

### BACKGROUND

To meet people's needs, electronic devices can achieve more and more functions.

Existing electronic devices are generally provided with photosensitive elements to achieve functions such as optical fingerprint recognition.

### SUMMARY

In an aspect, embodiments of the present application provide a display panel comprising: a substrate; a photosensitive element located at a side of the substrate, wherein an area where the photosensitive element is located is a light-sensing recognition area, and the light-sensing recognition area is located in a display area of the display panel; a first planarization layer located on a side of the photosensitive element away from the substrate; and a light-emission element located on a side of the first planarization layer away from the substrate, wherein in the light-sensing recognition area, a light transmittance of the first planarization layer is greater than or equal to 67%.

In another aspect, embodiments of the present application provide a display panel comprising: a substrate; a photosensitive element located at a side of the substrate, wherein an area where the photosensitive element is located is a light-sensing recognition area, and the light-sensing recognition area is located in a display area of the display panel; a first planarization layer located on a side of the photosensitive element away from the substrate; and a light-emission element located on a side of the first planarization layer away from the substrate, wherein in the light-sensing recognition area, a thickness of the first planarization layer is less than or equal to 3.05 μm and greater than or equal to 1.35 μm.

In another aspect, embodiments of the present application provide a display apparatus comprising the above-described display panel.

It should be understood that contents described in the present section are neither intended to identify key or important features of embodiments of the present application, nor intended to limit the scope of the present application. Other features of the present application will become readily understood in conjunction with the following description.

### BRIEF DESCRIPTION OF THE DRAWINGS

In order to illustrate technical solutions in exemplary embodiments of the present application more clearly, the drawings to be used in the description of the exemplary embodiments of will be briefly introduced below. It is obvious that the drawings described below are merely some embodiments of the present application, and for those of ordinary skill in the art, other drawings may be obtained based on these drawings without inventive efforts.

FIG. 1 shows a schematic structural view of a display panel according to embodiments of the present application;

FIG. 2 shows a schematic sectional structural view along A-A′ in FIG. 1;

FIG. 3 shows a schematic sectional structural view of a PIN structure according to embodiments of the present application;

FIG. 4 shows a schematic structural view of a fingerprint recognition module according to embodiments of the present application;

FIG. 5 shows a partial schematic sectional structural view of a display panel according to embodiments of the present application;

FIG. 6 shows a partial schematic sectional structural view of another display panel according to embodiments of the present application;

FIG. 7 shows a flow chart of a processing method of a first planarization layer according to embodiments of the present application;

FIG. 8 shows a partial schematic sectional structural view of still another display panel according to embodiments of the present application;

FIG. 9 shows a flow chart of another processing method of the first planarization layer according to embodiments of the present application;

FIG. 10 shows a partial schematic sectional structural view of still another display panel according to embodiments of the present application;

FIG. 11 shows a partial schematic sectional structural view of still another display panel according to embodiments of the present application; and

FIG. 12 shows a schematic structural view of a display apparatus according to embodiments of the present application.

### DETAILED DESCRIPTION

In order to enable those skilled in the art to better understand the technical solutions in the present application, the technical solutions in the embodiments of the present application will be described clearly and completely in conjunction with the accompanying drawings for the embodiments of the present application. Obviously, the described embodiments are merely a part of and not all of the embodiments of the present application. Based on the embodiments in the present application, all other embodiments obtained by those ordinary skilled in the art without any creative work shall fall within the protection scope of the present application.

The terms “first”, “second” and the like in the description, claims and the above description of the accompanying drawings of the present application are used for distinguishing similar objects, and not necessarily for describing a specific order or priority in order. It should be understood that the data used in this manner is interchangeable under appropriate conditions, so that the implementations or embodiments of the present application described herein can be implemented in other orders than illustrated or described herein. Moreover, the terms “comprising” and “including”, as well as any variation thereof, are intended to cover a non-exclusive inclusion, for example, they include a process, a method, a system, a product, or a device of a series of steps or units, and are not limited to the steps or units listed expressly, but may include other steps or units that are not listed expressly.

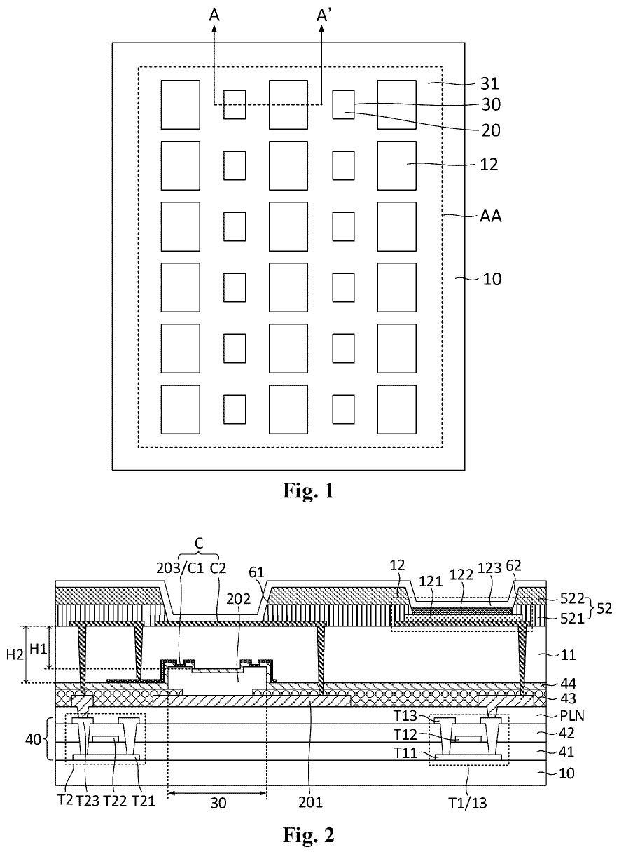

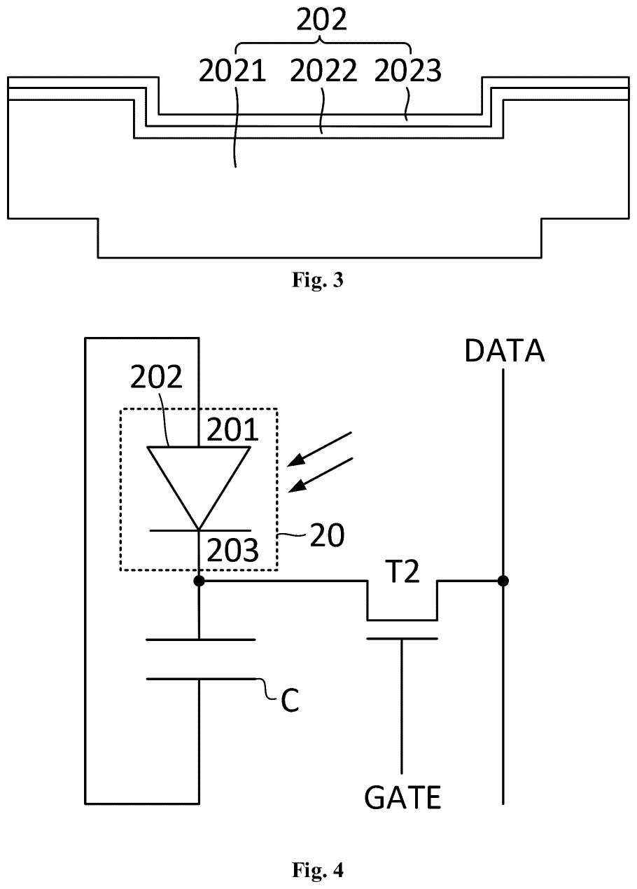

FIG. 1 shows a schematic structural view of a display panel according to embodiments of the present application; FIG. 2 shows a schematic sectional structural view along A-A′ in FIG. 1; FIG. 3 shows a schematic sectional structural view of a PIN structure according to embodiments of the present application; FIG. 4 shows a schematic structural view of a fingerprint recognition module according to embodiments of the present application. As shown in FIGS. 1-4, the display panel provided in embodiments of the present application comprises: a substrate 10; a photosensitive element 20 disposed at one side of the substrate 10, wherein an area where the photosensitive element 20 is located is a light-sensing recognition area 30 located in a display area AA of the display panel; a first planarization layer 11 disposed at the side of the photosensitive element 20 away from the substrate 10; and a light-emission element 12 disposed at the side of the first planarization layer 11 away from the base substrate 10, wherein in the light-sensing recognition area 30, the light transmittance of the first planarization layer 11 is greater than or equal to 67%.

Specifically, as shown in FIGS. 1 and 2, the substrate 10 is for carrying components such as a plurality of photosensitive elements 20 arranged in an array and a plurality of light-emission elements 12 arranged in an array. The substrate 10 can be a glass substrate to have relatively high hardness and scratch resistance, which can withstand large mechanical stress during manufacturing and use, thereby reducing damage risk. Additionally, it can also provide relatively high surface flatness and smoothness, which facilitates the uniformity of subsequent deposited film layers (such as array layers), thereby reducing film defects and non-uniformity. In other embodiments, the substrate 10 may be made of other materials such as flexible substrates (such as PI), which are not specifically limited in embodiments of the present application.

The display area AA of the display panel is provided with a plurality of pixel circuits 13 arranged in an array and a plurality of light-emission elements 12 arranged in an array, each of the pixel circuits 13 is electrically connected to the corresponding light-emission element 12, and the pixel circuits 13 are for transmitting driving current to the light-emission elements 12 under the action of signals of driving signal lines (such as scanning signal lines, data signal lines, and power supply signal lines) on the display panel, thereby driving the light-emission elements 12 to emit light. The light-emission elements 12 and the pixel circuits 13 electrically connected thereto together constitute sub-pixels of the display panel, a plurality of sub-pixels are arranged according to a certain rule, and a complete image can be displayed by precisely controlling the brightness of different sub-pixels.

It should be noted that the arrangements of the pixel circuits 13 and the light-emission elements 12 may be set according to actual needs, which are not particularly limited in embodiments of the present application.

Optionally, as shown in FIG. 2, the pixel circuit 13 may include at least one first thin film transistor T1, wherein the first thin film transistor T1 may include a first active layer T11, a first gate electrode T12, and a first source-drain electrode T13 that are stacked.

Further, as shown in FIG. 2, a gate insulating layer 41 is disposed between the first active layer T11 and the first gate electrode T12, and an interlayer insulating layer 42 is disposed between the first gate electrode T12 and the first source-drain electrode T13 to electrically isolate between the first gate electrode T12 and the first active layer T11 and between the first gate electrode T12 and the first source-drain electrode T13, thereby ensuring normal operation of the first thin film transistor T1.

The pixel circuit 13 may be a 1T1C circuit, a 2T1C circuit, a 7T1C circuit, a 8T1C circuit, or other types of pixel circuits known to those skilled in the art, and the specific structure of the pixel circuit 13 may be set according to the actual needs of the display panel, which is not limited in embodiments of the present application.

Further, the light-emission element 12 may include an Organic Light-Emitting Diode (OLED), a micro light-emitting diode (such as a Micro-LED or a Mini-LED), or other types of light-emission devices, which is not specifically limited in embodiments of the present application.

As shown in FIG. 2, taking the light-emission element 12 as an OLED for example, the light-emission element 12 may include an anode 121, a light-emission layer 122, and a cathode 123 that are stacked. When the pixel circuit 13 provides driving current to the light-emission element 12, electrons are injected into the light-emission layer 122 through the cathode 123, holes are injected into the light-emission layer 122 through the anode 121, and the electrons and holes recombine in the light-emission layer 122 to release energy, thereby causing the light-emission layer 122 to emit visible light.

In addition, visible light of different colors can be emitted by using different materials of the light-emission layer 122. For example, the light-emission element 12 may include a red light-emission element emitting red light, a blue light-emission element emitting blue light, and a green light-emission element emitting green light to achieve color image display, but is not limited thereto. In some embodiments, the light-emission element 12 may further include a white light-emission element emitting white light, which is not specifically limited in embodiments of the present application.

Further, as shown in FIGS. 1 and 2, the display area AA of the display panel is provided with a plurality of photosensitive elements 20 arranged in an array, and the photosensitive elements 20 are for receiving optical signals and converting the optical signals into electrical signals.

Optionally, as shown in FIG. 2, the photosensitive element 20 includes a first electrode 201, a PIN structure 202, and a second electrode 203 that are stacked in sequence.

As shown in FIG. 3, the PIN structure 202 includes a P-type semiconductor layer 2021, an intrinsic semiconductor layer 2022, and an N-type semiconductor layer 2023 that are stacked in sequence, wherein the P-type semiconductor layer 2021 is P-type doped, the intrinsic semiconductor layer 2022 is undoped, and the N-type semiconductor layer 2023 is N-type doped. The N-type semiconductor layer 2023 can increase the concentration of free electrons by being doped with pentavalent elements (such as phosphorus and arsenic), and it can provide a large amount of free electrons, which can be injected into the intrinsic semiconductor layer 2022 when the PIN structure 202 is forward-biased, and ultimately reach the P-type semiconductor layer 2021. The intrinsic semiconductor layer 2022 is an undoped pure semiconductor material with a very low carrier concentration and can provide a high-resistance region. When the PIN structure 202 is reverse-biased, the intrinsic semiconductor layer 2022 can effectively block the flow of carriers, allowing it to withstand high voltages without breakdown; and when the PIN structure 202 is forward-biased, the intrinsic semiconductor layer 2022 permits the passage of carriers (such as electrons and holes). The P-type semiconductor layer 2021 can increase the hole concentration by doping a trivalent element (such as boron and aluminum), and when the PIN structure 202 is forward-biased, the P-type semiconductor layer 2021 receives electrons injected from the N-type semiconductor layer 2023, and the electrons recombine with holes in the P-type semiconductor layer 2021 to generate an electric current.

Further, the P-type semiconductor layer 2021 is electrically connected to the first electrode 201, and the N-type semiconductor layer 2023 is electrically connected to the second electrode 203, so that the first electrode 201, the PIN structure 202, and the second electrode 203 constitute a photodiode; and under this condition, the first electrode 201 serves as the anode of the photodiode, and the second electrode 203 serves as the cathode of the photodiode.

The PIN structure 202 has photosensitive properties and unidirectional conductivity. When not exposed to light, the PIN structure 202 has a small reverse saturation leakage current, and the photodiode is off. When exposed to light, the reverse saturation leakage current of the PIN structure 202 significantly increases, thereby generating a photocurrent.

Optionally, the photosensitive element 20 may be used for achieving a fingerprint recognition function or other biometric recognition function.

For example, as shown in FIG. 4, the photosensitive element 20, together with a storage capacitor C and the second thin-film transistor T2, can form a fingerprint recognition module, wherein the storage capacitor C is connected in series between the first electrode 201 and the second electrode 203 of the photodiode, the second thin-film transistor T2 is connected in series between the first electrode 201 and the signal line DATA, and the gate electrode of the second thin film transistor T2 is electrically connected to the switch control line GATE. The PIN structure 202 of the photodiode is connected between the first electrode 201 and the second electrode 203.

The working principle of the fingerprint recognition module can be described as follows: during fingerprint recognition, at least the light-emission elements in a finger touch area emit light to be incident on a finger; the reflected light from the finger is incident on the PIN structure 202, which generates a photocurrent under the effect of the reflected light; because the distance between the ridges of the fingerprint and the PIN structure 202 is different from the distance between the valleys of the fingerprint and the PIN structure 202, the intensity of the reflected light received by the PIN structure 202 at the ridges differs from that at the valleys, whereby the photocurrent generated varies in magnitude; and therefore the ridge signals and valley signals can be distinguished according to the photocurrent, thereby enabling fingerprint recognition.

Exemplarily, in a fingerprint recognition stage, a low voltage signal is input to the first electrode 201 of the photosensitive element 20, and a high voltage signal is input to the signal line DATA. The entire fingerprint recognition stage may include a preparation stage, a fingerprint signal acquisition stage, and a fingerprint signal detection stage. In the preparation stage, a driver chip (not shown in the figure) electrically connected to the fingerprint recognition module controls the second thin film transistor T2 to turn on through the switch control line GATE, and the storage capacitor C is charged until the charging process is completed, forming a fixed voltage difference across the storage capacitor C. In the fingerprint recognition stage, the switch control line GATE controls the second thin film transistor T2 to turn off; when a finger touches the display panel, the light emitted by the light-emission element 12 is incident on the finger and is reflected on the surface of the finger to form a reflected light incident on the PIN structure 202, and the PIN structure 202 receives the reflected light and generates a corresponding photocurrent according to the intensity of the received reflected light, which may affect the potential of the storage capacitor C, so that the storage capacitor C generates a voltage drop. In the fingerprint signal detection stage, the switching control line GATE controls the second thin film transistor T2 to turn on, whereby the signal line DATA can read information about the potential of the storage capacitor C, thereby acquiring the voltage drop of the storage capacitor C. When multiple fingerprint recognition modules are arranged in an array, since the surface of the finger is uneven due to the fingerprint, the reflected light is rendered with distinct brightness levels; and therefore the photocurrents generated by different PIN structures 202 vary in magnitude, leading to different voltage drops across the corresponding storage capacitors C, so that the ridge and valley signals can be distinguished according to the voltage drops across the storage capacitors C, thereby enabling the fingerprint recognition function of the display panel.

In some embodiments, in the fingerprint signal detection stage, the switch control line GATE can control the second thin film transistor T2 to turn on, there is a potential difference between the two electrodes of the storage capacitor C, and the storage capacitor C is in a charged state, and the magnitude of the photocurrent may be determined by detecting the amount of charge charged by the storage capacitor C to achieve the fingerprint recognition of the display panel.

Optionally, still referring to FIG. 2, the second thin film transistor T2 may include a second active layer T21, a second gate electrode T22, and a second source-drain electrode T23 that are stacked. The second thin film transistor T2 and the first thin film transistor T1 may be located in the same film layer, i.e., the second thin film transistor T2 is disposed in the array layer 40 including the pixel circuit 13, such that the number of film layers disposed can be reduced, which is beneficial to reducing the thickness of the display panel; and under this condition, the second thin film transistor T2 can be manufactured in the same process as the first thin film transistor T1, which is beneficial to shortening the process time and reducing the manufacturing cost.

It should be noted that the array layer 40 usually includes a plurality of metal traces to transmit signals for driving the pixel circuit 13 to work. Optionally, as shown in FIG. 2, the array layer 40 is located between the substrate 10 and the light-emission element 12 in a direction perpendicular to the plane where the substrate 10 is located, which can prevent the light emitted by the light-emission element 12 from being blocked by the metal traces in the array layer 40, thereby ensuring the light-emission efficiency of the display panel; and under this condition, the array layer 40 is located between the substrate 10 and the photosensitive element 20, and the photosensitive element 20 can be prevented from being blocked by the metal traces in the array layer 40, thereby ensuring the photosensitivity of the photosensitive element 20.

Further, the array layer 40 usually includes a plurality of thin film transistors and a plurality of metal traces, and these structures may cause the upper surface of the array layer 40 uneven. In an embodiment, as shown in FIG. 2, a planarization layer PLN may be disposed between the array layer 40 and the photosensitive element 20 in the direction perpendicular to the plane where the substrate 10 is located, and the planarization layer PLN is used for planarization, thereby providing a flat surface for manufacturing the photosensitive element 20 over the array layer 40, which is beneficial to ensuring the uniform performance of each photosensitive element 20.

Optionally, still referring to FIG. 2, the storage capacitor C includes a first electrode plate C1 and a second electrode plate C2 that are stacked, and the first electrode plate C1 is located at the side of the second electrode plate C2 close to the substrate 10. The first electrode plate C1 is electrically connected to the second electrode 203, and the second electrode plate C2 is electrically connected to the first electrode 201.

Optionally, as shown in FIG. 2, the second electrode plate C2 is electrically connected to the cathode 123 to achieve the input of a low voltage signal to the first electrode 201 of the photosensitive element 20, but is not limited thereto.

Optionally, as shown in FIG. 2, the first electrode plate C1 and the second electrode 203 have the same structure, such that the number of film layers disposed can be reduced, which is beneficial to reducing the thickness of the display panel, thereby shortening the process time and reducing the manufacturing cost.

Optionally, as shown in FIG. 2, the material of the second electrode plate C2 may be a transparent conductive material to increase the light transmittance of the second electrode plate C2, so that more light can impinge on the photosensitive element 20 through the second electrode plate C2, thereby improving the photosensitivity of the photosensitive element 20. When the photosensitive element 20 is used for fingerprint recognition, it is beneficial to improving the fingerprint recognition efficiency.

The material of the second electrode plate C2 may include a transparent material such as indium tin oxide (ITO) or indium zinc oxide (IZO) to achieve conductive and light transmission effects, but is not limited thereto, and the embodiments of the present application does not particularly limit thereto.

It should be noted that the specific structure of the fingerprint recognition module is not limited to the structure provided in the above-described embodiments, and in other embodiments, the function and specific structure of the photosensitive element 20, the circuit connection relationship, and the film layer arrangement can be set according to actual needs, which are not limited in embodiments of the present application.

Further, as shown in FIGS. 1 and 2, in this embodiment, the photosensitive element 20 is disposed inside the display panel, and the light emitted by the light-emission element 12 of the display panel can be used as a light source to achieve the fingerprint recognition and detection.

The area where the photosensitive element 20 is located is a light-sensing recognition area 30, and the light-sensing recognition area 30 is located between adjacent two of the light-emission elements 12 in a direction parallel to the plane where the substrate 10 is located, i.e., the photosensitive element 20 is arranged at the gap position between the adjacent light-emitting elements 12, so that the fingerprint recognition function can be achieved by effectively using the light emitted by the adjacent light-emitting elements 12 while the photosensitive element 20 does not affect the opening ratio of the display panel.

Still referring to FIGS. 1 and 2, the array layer 40 usually includes a plurality of thin film transistors and a plurality of metal traces. These structures may cause the upper surface of the array layer 40 uneven. In an embodiment, as shown in FIG. 2, a planarization layer PLN may be disposed between the array layer 40 and the photosensitive element 20 in the direction perpendicular to the plane where the substrate 10 is located, and the planarization layer PLN is used for planarization, thereby providing a flat surface for manufacturing the photosensitive element 20 over the array layer 40, which is beneficial to ensuring the uniform performance of each photosensitive element 20.

The inventors have found that, after the photosensitive element 20 is embedded in the display panel, some superimposed film layers (such as the first electrode 201, the PIN structure 202, the second electrode 203, and other related structures) are added above the array layer 40, and the added film layers can form a step on the planarization layer PLN, which may affect the flatness of film layers above the planarization layer PLN. For example, the flatness of the anode 121 is affected, resulting in the uneven height of the light-emission layer 122 above the anode 121, so that when the display panel is viewed at the same inclination angle in different azimuth, the brightness of the light-emission layer 122 varies, resulting in inconsistent color shift at the same viewing angle in different azimuths, i.e., there is a problem of four-azimuth color shift inconsistency affecting the display performance of the display panel.

Based on the above technical problem, as shown in FIG. 2, in this embodiment, the first planarization layer 11 is disposed between the photosensitive element 20 and the light-emission element 12 in a direction perpendicular to the plane where the substrate 10 is located, and the first planarization layer 11 plays the role of planarization, thereby providing a relatively flat surface for manufacturing the light-emission element 12, ensuring that the film layers (such as the anode 121 and the light-emission layer 122) above the first planarization layer 11 can be uniformly deposited, and avoiding a color shift caused by surface unevenness.

The inventors have further found that since the photosensitive element 20 has a relatively large thickness, a relatively large step (e.g., a step height of approximately 2 μm) may be formed on the planarization layer PLN; therefore, to eliminate the interference of the step, it is necessary to dispose the first planarization layer 11 having a relatively large thickness over the photosensitive element 20. However, the first planarization layer 11 having the relatively large thickness may cause the light transmittance of the first planarization layer 11 to decrease (e.g., the light transmittance decreases to less than 50%), thereby directly affecting the response of the photosensitive element 20 to light.

Specifically, the photocurrent generated by the photosensitive element 20 is proportional to the number of photons received by the intrinsic semiconductor layer 2022 thereof. In this embodiment, the first planarization layer 11 is located over the photosensitive element 20, and external light needs to pass through the first planarization layer 11 to impinge on the photosensitive element 20. Therefore, the light transmittance of the first planarization layer 11 is reduced, which may cause the reduction of the number of photons passing through the first planarization layer 11, thereby reducing the number of photons received by the intrinsic semiconductor layer 2022 in the photosensitive element 20 and causing the decrease of the photocurrent, such that the fingerprint recognition efficiency or the performance of other photosensitive elements 20 may be affected.

In view of the above technical problem, in this embodiment, the light transmittance of the first planarization layer 11 in the light-sensing recognition area 30 is set to be greater than or equal to 67% to improve the light transmittance of the first planarization layer 11 over the photosensitive element 20, so that more external light can pass through the first planarization layer 11 and impinge on the photosensitive element 20, thereby increasing the number of photons received by the intrinsic semiconductor layer 2022 in the photosensitive element 20, and improving the photocurrent. Thus, the performance of the photosensitive element 20 can meet the application requirements (e.g., improving the fingerprint recognition efficiency).

The light transmittance of the first planarization layer 11 in the light-sensing recognition area 30 can achieve 67% by, but is not limited to, the following means.
1. For the first planarization layer 11, a planarization material having a relatively high light transmittance, such as an organic material with higher transparency, is selected to ensure that more light can smoothly pass through the first planarization layer 11 and impinge on the photosensitive element 20 to improve the photocurrent.
2. The thickness of the first planarization layer 11 in the light-sensing recognition area 30 is reduced to reduce the light absorption and reflection by the first planarization layer 11, thereby ensuring that more light can smoothly pass through the first planarization layer 11 and impinge on the photosensitive element 20 and increasing the photocurrent.

In summary, in the display panel provided in embodiments of the present application, photosensitive elements are disposed inside the display panel, and a first planarization layer is disposed between the photosensitive elements and the light-emission elements for planarization to eliminate the influence of the step introduced by photosensitive elements and avoid the color shift caused by surface unevenness. Further, the light transmittance of the first planarization layer in the light-sensing recognition area is set to be greater than or equal to 67% to improve the light transmittance of the first planarization layer on the photosensitive element, so that more external light can pass through the first planarization layer and impinge on the photosensitive element, thereby increasing the number of photons received by the photosensitive element, improving the photocurrent, and further improving the performance of the photosensitive element.

Optionally, the light transmittance of the first planarization layer 11 for a first-wavelength light is greater than or equal to 67%, the wavelength of the first-wavelength light is 21, and 380 nm≤λ1≤435 nm.

The inventors have found that the commonly used material of the first planarization layer 11 has a relatively low light transmittance in the short-wavelength band (e.g., the light transmittance to blue light is reduced to less than 50%), thereby directly affecting the response of the photosensitive element 20 to blue light.

In this embodiment, the first planarization layer 11 is provided with a light transmittance greater than or equal to 67% for the first-wavelength light (such as blue light having a wavelength of 380 nm to 435 nm), the light transmittance of the first planarization layer 11 on the photosensitive element 20 for the first-wavelength light can be improved, and more first-wavelength light can pass through the first planarization layer 11 to impinge on the photosensitive element 20, thereby increasing the first-wavelength light received by the photosensitive element 20, improving the blue light photocurrent, and further enabling the performance of the photosensitive element 20 to meet the application requirements.

Optionally, the light transmittance of the first planarization layer 11 for a second-wavelength light is greater than or equal to the light transmittance of the first planarization layer 11 for the first-wavelength light, the wavelength of the second-wavelength light is λ2, and λ2>435 nm.

The photosensitive performance of the photosensitive element 20 depends on not only the response to the first-wavelength light (such as the blue light having a wavelength of 380 nm to 435 nm), but also the response to light having a relatively long wavelength (such as the green light and red light).

Therefore, in this embodiment, the light transmittance of the first planarization layer 11 for the second-wavelength light (such as the light having a wavelength greater than 435 nm) is greater than or equal to the light transmittance for the first-wavelength light (such as the blue light having a wavelength of 380 nm to 435 nm), so that the light transmittance of the first planarization layer 11 over the photosensitive element 20 for the second-wavelength light can be improved, and more second-wavelength light can impinge on the photosensitive element 20, thereby increasing the second-wavelength light received by the photosensitive element 20 and improving the light photocurrent. Thus, the performance of the photosensitive element 20 can meet the application requirements (e.g., improving the fingerprint recognition efficiency).

Optionally, the material of the first planarization layer 11 includes at least one of polyimide or polymethyl methacrylate.

Polyimide (PI) and polymethyl methacrylate (PMMA) have a relatively high light transmittance, especially for light in the short-wavelength band.

In this embodiment, the material of the first planarization layer 11 is replaced with at least one of PI or PMMA, whereby the light transmittance of the first planarization layer 11 can be improved under the condition that the thickness of the first planarization layer 11 is unchanged, so that more light can pass through the first planarization layer 11 and impinge on the photosensitive element 20 while ensuring the planarization effect, thereby increasing the number of photons received by the photosensitive element 20 and improving the photocurrent. Thus, the performance of the photosensitive element 20 can meet the application requirements (e.g., improving the fingerprint recognition efficiency).

Exemplarily, the material of the first planarization layer 11 is replaced with at least one of PI or PMMA; when the thickness of the first planarization layer 11 is 2 μm, the light transmittance of the first planarization layer 11 for the light having a wavelength of 400 nm can be increased from 75% to 90%; when the thickness of the first planarization layer 11 is 4 μm, the light transmittance of the first planarization layer 11 for the light having a wavelength of 400 nm can be increased from 58% to 84%, thereby obviously improving the light transmittance of the first planarization layer 11 in the short-wavelength band, which is beneficial to increasing the number of photons received by the photosensitive element 20 through the first planarization layer 11 and improving the photocurrent. Thus, the performance of the photosensitive element 20 can meet the application requirements (e.g., improving the fingerprint recognition efficiency).

It should be noted that the molecular structure of a material directly affects its optical properties, especially the light absorption and scattering characteristics. In this embodiment, the molecular structure of the material (such as polyimide or polymethyl methacrylate) of the first planarization layer 11 can be adjusted, and the refractive index, absorption coefficient, and scattering coefficient of the material can be changed, thereby significantly improving the light transmittance thereof.

For example, by adjusting the molecular structure of the material (such as polyimide or polymethyl methacrylate) of the first planarization layer 11, the absorption of the material for the light having a specific wavelength is reduced, particularly the absorption in the short-wavelength band (such as blue light).

Alternatively, by adjusting the molecular structure of the material (such as polyimide or polymethyl methacrylate) of the first planarization layer 11, the refractive index of the material is closer to the refractive index of air or other medium to reduce the reflection loss of light at the interface.

Alternatively, by adjusting the molecular structure of the material of the first planarization layer 11 (such as polyimide or polymethyl methacrylate), the surface of the material becomes more smooth and flat, and the scattering of light inside the material is reduced, which is not limited thereto.

Optionally, still referring to FIG. 2, the material of the first planarization layer 11 and the material of the planarization layer PLN are different, so that the light transmittance of the first planarization layer 11 per unit thickness is greater than the light transmittance of the planarization layer PLN per unit thickness.

In this embodiment, the first planarization layer 11 and the planarization layer PLN may be made of different materials, so that the material selection of the first planarization layer 11 and the planarization layer PLN is more extensive and practical.

As shown in FIG. 2, the planarization layer PLN is located under the photosensitive element 20 and does not affect the number of photons received by the photosensitive element 20. Therefore, a material having a better planarization effect is selected for the planarization layer PLN to ensure a good planarization effect.

The first planarization layer 11 is located over the photosensitive element 20, which directly affects the number of photons received by the photosensitive element 20. Therefore, the first planarization layer 11 can be made of a material with higher light transmittance to ensure high light transmittance, which is beneficial to improving the photocurrent of the photosensitive element 20.

FIG. 5 shows a partial schematic sectional structural view of a display panel according to embodiments of the present application. Optionally, as shown in FIG. 5, the first planarization layer 11 includes at least two planarization sub-layers 110, and at least two planarization sub-layers 110 are made of the same material.

To completely cover a relatively large step, the first planarization layer 11 has a relatively large thickness. If the first planarization layer 11 is provided as a single-layer structure, during the preparation of the first planarization layer 11, the material of the first planarization layer 11 may unevenly flow, causing the formation of a local thickness difference, which may affect the planarization effect.

In this embodiment, the first planarization layer 11 is divided into at least two planarization sub-layers 110, so that during the preparation of the first planarization layer 11, the planarization sub-layers 110 can be prepared layer by layer to gradually reduce the step, and eventually form a flatter surface to achieve a better planarization effect.

In FIG. 5, only the first planarization layer 11 having two planarization sub-layers 110 is taken as an example for description, but the present application is not limited thereto. In other embodiments, the number of the planarization sub-layers 110 in the first planarization layer 11 may be set according to actual needs, which is not specifically limited in embodiments of the present application.

Further, each of the planarization sub-layers 110 may be made of the same material, so that the difference between the respective refractive indexes of the planarization sub-layers 110 is relatively small, the reflection loss of light at the interface is reduced, which is beneficial to improving the light transmittance of the first planarization layer 11 as a whole, so that more light can pass through the first planarization layer 11 and reach the photosensitive element 20, thereby increasing the photocurrent.

It should be noted that the material of each planarization sub-layer 110 may be made of a material having a relatively high light transmittance (such as polyimide or polymethyl methacrylate) to improve the light transmittance of the first planarization layer 11, so that more light can pass through the first planarization layer 11 and impinge on the photosensitive element 20, increase the number of photons received by the photosensitive element 20, and improve the photocurrent. Thus, the performance of the photosensitive element 20 can meet the application requirements (e.g., improving the fingerprint recognition efficiency).

Optionally, still referring to FIG. 5, the first planarization layer 11 includes at least two planarization sub-layers 110, and in the planarization sub-layers 110, and the material of the planarization sub-layer 110 farthest from the substrate 10 is different from the material of the other planarization sub-layers 110.

As shown in FIG. 5, the first planarization layer 11 is divided into at least two planarization sub-layers 110, and the advantageous effects thereof can be referred to in the aforementioned embodiments, and will not be repeated here.

Further, as shown in FIG. 5, “the planarization sub-layer 110 farthest from the substrate 10” refers to the uppermost planarization sub-layer 110 in the first planarization layer 11, and “the other planarization sub-layer(s) 110” refers to the other planarization sub-layer(s) 110 in the first planarization layer 11 than the uppermost planarization sub-layer 110.

For example, as shown in FIG. 5, taking the first planarization layer 11 including two planarization sub-layers 110 as an example, two planarization sub-layers 110 are the first planarization sub-layer 110A and the second planarization sub-layer 110B, and the first planarization sub-layer 110A is located on the side of the second planarization sub-layer 110B close to the substrate, wherein the planarization sub-layer 110 farthest from the substrate 10 is the second planarization sub-layer 110B, and the other planarization sub-layer 110 is the first planarization sub-layer 110A.

In this embodiment, the material of the planarization sub-layer 110 farthest from the substrate 10 is different from the material of the other planarization sub-layers 110. For example, the material of the first planarization sub-layer 110A differs from that of the second planarization sub-layer 110B, so that the materials of the planarization sub-layer 110 farthest from the substrate 10 and the other planarization sub-layers 110 can be selected from a wider range of materials to combine the planarization performance and the light transmittance performance of the first planarization layer 11.

For example, as shown in FIG. 5, one of the first planarization sub-layer 110A and the second planarization sub-layer 110B is made of a material having a better planarization effect to ensure that the first planarization layer 11 has a good planarization effect; and the other one is made of a material having a higher light transmittance to ensure that the first planarization layer 11 has a higher light transmittance, which is beneficial to improving the photocurrent of the photosensitive element 20.

Optionally, still referring to FIG. 5, the light transmittance of the planarization sub-layer 110 farthest from the substrate 10 is greater than the light transmittance of the other planarization sub-layers 110.

During the preparation of the first planarization layer 11, the planarization sub-layer 110 except the uppermost planarization layer sub-layer 110 is first formed, and then the uppermost planarization sub-layer 110 is formed on the formed planarization sub-layer 110B. In this embodiment, the planarization sub-layer 110 except the uppermost planarization sub-layer 110 may be set to have a low light transmittance, thereby appropriately reducing the light transmittance requirement for the planarization sub-layer 110 except the uppermost planarization sub-layer 110. Thus, the planarization sub-layer 110 except the uppermost planarization sub-layer 110 can be made of a material having a better planarization effect, so that most of the steps can be eliminated before the formation of the uppermost planarization sub-layer 110, the light transmittance requirement for the uppermost planarization sub-layer 110 can be appropriately reduced without excessive concern for planarization effect, and the material of the uppermost planarization sub-layer 110 can be selected from a wider range.

Further, when the photosensitive element 20 operates, external light first enters the uppermost planarization sub-layer 110, then passes through the planarization sub-layer 110 except the uppermost planarization sub-layer 110, and finally impinges on the photosensitive element 20. In this embodiment, the uppermost planarization sub-layer 110 has a relatively high light transmittance. For example, the uppermost planarization sub-layer 110 is made of a material having a relatively high transmittance for blue light (380 nm≤λ1≤435 nm), which can significantly increase the amount of light entering the first planarization layer 11, thereby increasing the number of photons received by the photosensitive element 20 and improving the photocurrent. Thus, the performance of the photosensitive element 20 can meet the application requirements (e.g., improving the fingerprint recognition efficiency).

Optionally, the thickness of the first planarization layer 11 is greater than or equal to 2.2 μm.

Since the photosensitive element 20 has a relatively large thickness, a large step (e.g., a step of approximately 2 μm) may be formed on the planarization layer PLN. Therefore, in this embodiment, the first planarization layer 11 is disposed over the photosensitive element 20, and the thickness of the first planarization layer 11 is not less than 2.2 μm to effectively eliminate the influence of the step caused by the photosensitive element 20, provide a relatively flat surface for manufacturing the light-emission element 12, and ensure that the anode 121 and the light-emission layer 122 can be uniformly deposited over the first planarization layer 11, thereby avoiding the color shift caused by the uneven surface.

It should be noted that the specific thickness of the first planarization layer 11 can be set according to actual needs, and embodiments of the present application do not specifically limit to this.

Exemplarily, as shown in FIG. 5, the thickness of the first planarization sub-layer 110A may be 1.2 μm, the thickness of the second planarization sub-layer 110B may be 2.2 μm, and the thickness of the first planarization layer 11 may be approximately 3.05 μm in the light-sensing recognition area 30. By replacing the material of the first planarization layer 11 with at least one of PI or PMMA, the light transmittance of the first planarization layer 11 for the light having a wavelength of 400 nm can achieve 87% in the light-sensing recognition area 30, so that the light transmittance of the first planarization layer 11 in the short-wavelength band is improved, which is beneficial to increasing the number of photons received by the photosensitive element 20 through the first planarization layer 11 and improving the photocurrent. Thus, the performance of the photosensitive element 20 can meet the application requirements (e.g., improving the fingerprint recognition efficiency).

Optionally, still referring to FIG. 5, the first planarization layer 11 includes at least two planarization sub-layers 110, at least two planarization sub-layers 110 include a first planarization sub-layer 110A and a second planarization sub-layer 110B, the first planarization sub-layer 110A is located on the side of the second planarization sub-layer 110B close to the substrate 10, and the thickness of the second planarization sub-layer 110B is greater than the thickness of the first planarization sub-layer 110A.

During the preparation of the first planarization layer 11, the first planarization sub-layer 110A is first formed on the photosensitive element 20. In this embodiment, since the surface morphology of the photosensitive element 20 is relatively complex, the first planarization sub-layer 110A is provided with a relatively small thickness, so that the first planarization sub-layer 110A can fill details on the complex surface of the photosensitive element 20 to ensure that every tiny step can be effectively covered, and the formation of defects such as holes can be reduced, whereby a better surface basis can be provided for the subsequent planarization step.

Further, on the basis of the first planarization sub-layer 110A, a second planarization sub-layer 110B is formed. In this embodiment, since the first planarization sub-layer 110A has preliminarily filled tiny steps, the second planarization sub-layer 110B is provided with a relatively large thickness to further eliminate relatively large steps and ensure a relatively good planarization effect.

The specific thicknesses of the first planarization sub-layer 110A and the second planarization sub-layer 110B may be set according to actual needs. For example, the thickness of the first planarization sub-layer 110A may be 1 μm to 2.2 μm, so that the first planarization sub-layer 110A can effectively fill tiny steps and provide a relatively good planarization effect. The thickness of the second planarization sub-layer 110B may be greater than or equal to 2.2 μm to effectively eliminate the step caused by the photosensitive element 20, provide a relatively flat surface for manufacturing the light-emission element 12, and ensure that the film layer such as the anode 121 and the light-emission layer 122 located above the first planarization layer 11 can be uniformly deposited, thereby avoiding the color shift caused by surface unevenness, which is not limited thereto and is not specifically limited in embodiments of the present application.

Optionally, still referring to FIGS. 1, 2, and 5, an area in the display area AA except the light-sensing recognition area 30 is a non-light-sensing recognition region 31, and the thickness H1 of the first planarization layer 11 in the light-sensing recognition area 30 is smaller than the thickness H2 of the first planarization layer 11 in the non-light-sensing recognition area 31.

It should be understood that the light-sensing recognition area 30 is mainly used for sensing and recognizing external light, such as under-screen fingerprint recognition and optical sensing. When the photosensitive element 20 operates, most of the external light impinges on the photosensitive element 20 through the first planarization layer 11 located in the light-sensing recognition area 30, and is converted into an electrical signal by the photosensitive element 20.

In this embodiment, as shown in FIG. 5, the thickness H1 of the first planarization layer 11 in the light-sensing recognition area 30 is relatively small to improve the light transmittance of the first planarization layer 11 on the photosensitive element 20, so that more light can pass through the first planarization layer 11 in the light-sensing recognition area 30 and impinges on the photosensitive element 20, increase the number of photons received by the photosensitive element 20, and improve the photocurrent. Thus, the performance of the photosensitive element 20 can meet the application requirements (e.g., improving the fingerprint recognition efficiency).

Further, the non-light-sensing recognition area 31 is not for sensing or recognizing external light, and is mainly for displaying images and other functions, so the first planarization layer 11 of the non-light-sensing recognition area 31 may be used for providing a planarization effect.

In this embodiment, the thickness H2 of the first planarization layer 11 in the non-light-sensing recognition area 31 is relatively large, which can more effectively eliminate the step caused by the photosensitive element 20, provide a relatively flat surface for manufacturing the light-emission element 12, and ensure that the film layer such as the anode 121 and the light-emission layer 122 located above the first planarization layer 11 can be uniformly deposited, thereby avoiding the color shift caused by surface unevenness.

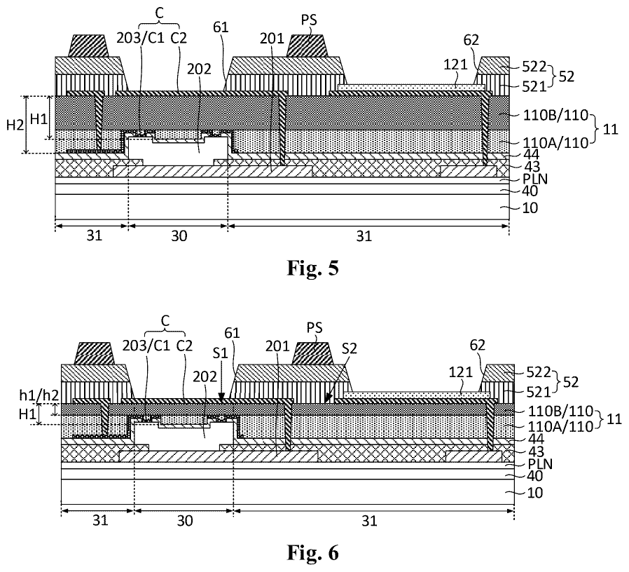

FIG. 6 shows a partial schematic sectional structural view of another display panel according to embodiments of the present application. Optionally, as shown in FIG. 6, in the light-sensing recognition area 30, the thickness H1 of the first planarization layer 11 is less than or equal to 3.05 μm and greater than or equal to 1.35 μm.

After the formation of the first planarization layer 11, the light transmittance of the first planarization layer 11 may be improved by reducing the thickness of the first planarization layer 11.

Specifically, as shown in FIG. 6, the thickness H1 of at least a portion of the first planarization layer 11 within the light-sensing recognition area 30 may be reduced to less than or equal to 3.05 μm, thereby improving the light transmittance of the first planarization layer 11 in the light-sensing recognition area 30, enabling more light to pass through the first planarization layer 11 to impinge on the photosensitive element 20, increasing the number of photons received by the photosensitive element 20, and improving the photocurrent. Thus, the performance of the photosensitive element 20 can meet the application requirements (e.g., improving the fingerprint recognition efficiency).

Meanwhile, the thickness H1 of the first planarization layer 11 in the light-sensing recognition area 30 is set to be greater than or equal to 1.35 μm, which can ensure that the first planarization layer 11 can still completely cover the photosensitive element 20 even in the case of process error, can provide effective protection for the photosensitive element 20 while ensuring the planarization effect, and is beneficial to avoiding the photosensitive element 20 being damaged in the subsequent process, thereby improving the reliability and stability of the photosensitive element 20.

It should be noted that the specific thickness of the first planarization layer 11 in the light-sensing recognition area 30 may be set according to actual needs. For example, as shown in FIG. 6, the thickness H1 of the first planarization layer 11 in the light-sensing recognition area 30 may be 1.6 μm to improve the light transmittance of the first planarization layer 11 in the light-sensing recognition area 30 while ensuring the planarization effect, which is not limited thereto and is not specifically limited in embodiments of the present application.

Optionally, still referring to FIG. 6, the first planarization layer 11 includes a first planarization sub-layer 110A and a second planarization sub-layer 110B, and the first planarization sub-layer 110A is located on the side of the second planarization sub-layer 110B close to the substrate 10. In the light-sensing recognition area 30, the thickness h1 of the second planarization sub-layer 110B is greater than or equal to 0.5 μm.

The specific structures and beneficial effects of the first planarization sub-layer 110A and the second planarization sub-layer 110B may be referred to the above-described embodiments, which is not be repeated here.

In this embodiment, the thickness of the second planarization sub-layer 110B in the light-sensing recognition area 30 is set to be greater than or equal to 0.5 μm, which can prevent the second planarization sub-layer 110B in the light-sensing recognition area 30 from cracking or peeling to ensure the planarization effect of the second planarization sub-layer 110B. Therefore, it is beneficial to providing a relatively flat surface for manufacturing the light-emission element 12 and ensuring that the film layer such as the anode 121 and the light-emission layer 122 located above the first planarization layer 11 can be uniformly deposited, thereby avoiding the color shift caused by surface unevenness.

Optionally, still referring to FIG. 6, in the light-sensing recognition area 30, the surface of the first planarization layer 11 away from the substrate 10 is the first surface S1. In the non-light-sensing recognition area 31, the surface of the first planarization layer 11 away from the substrate 10 is the second surface S2. The distance between the first surface S1 and the second surface S2 is less than or equal to 0.5 μm in a direction perpendicular to the plane where the substrate 10 is located.

Specifically, as shown in FIG. 6, a first surface S1 is the upper surface of the first planarization layer 11 in the light-sensing recognition area 30, and a second surface S2 is the upper surface of the first planarization layer 11 in the non-light-sensing recognition area 31.

When there is a relatively large height difference between the first surface S1 of the first planarization layer 11 in the light-sensing recognition area 30 and the second surface S2 of the first planarization layer 11 in the non-light-sensing recognition area 31, obvious pits are formed on the upper surface of the first planarization layer 11, so that part of the light is refracted or scattered on the sidewall of the pits, causing the part of the light to fail to reach the photosensitive element 20 and the decrease of the photocurrent of the photosensitive element 20, thereby affecting the fingerprint recognition efficiency or the performance of other photosensitive elements 20.

In this embodiment, the height difference between the first surface S1 of the first planarization layer 11 in the light-sensing recognition area 30 and the second surface S2 of the first planarization layer 11 in the non-light-sensing recognition area 31 is less than or equal to 0.5 μm, which can reduce the coverage area of the sidewall of the pits, thereby reducing the amount of the light refracted or scattered on the sidewall of the pits, enabling more external light to pass through the first planarization layer 11 of the light-sensing recognition area 30 to impinge on the photosensitive element 20, and improving the photocurrent. Thus, the performance of the photosensitive element 20 can meet the application requirements (e.g., improving the fingerprint recognition efficiency).

Meanwhile, a height difference between the first surface S1 of the first planarization layer 11 in the light-sensing recognition area 30 and the second surface S2 of the first planarization layer 11 in the non-light-sensing recognition area 31 is relatively small, which is beneficial to eliminate the step caused by the photosensitive element 20, provide a relatively flat surface for the preparation of the light-emission element 12, and ensure that the film layer such as the anode 121 and the light-emission layer 122 on the first planarization layer 11 can be uniformly deposited, thereby avoiding the color shift caused by surface unevenness. Further, as shown in FIG. 6, the first surface S1 of the first planarization layer 11 in the light-sensing recognition area 30 is flush with the second surface S2 of the first planarization layer 11 in the non-light-sensing recognition area 31, i.e., the first surface S1 of the first planarization layer 11 in the light-sensing recognition area 30 and the second surface S2 of the first planarization layer 11 in the non-light-sensing recognition area 31 are located on the same horizontal plane. In this case, the height of the first surface S1 is equal to that of the second surface S2, such that the pits on the upper surface of the first planarization layer 11 can be eliminated, thereby reducing the amount of the light refracted or scattered on the sidewall of the pits, enabling more external light to pass through the first planarization layer 11 of the light-sensing recognition area 30 to impinge on the photosensitive element 20, and improving the photocurrent. In addition, it can ensure that the step caused by the photosensitive element 20 is eliminated, a flat surface for manufacturing the light-emission element 12 is provided, and the color shift caused by surface unevenness is avoided.

Optionally, still referring to FIG. 6, the first planarization layer 11 includes a first planarization sub-layer 110A and a second planarization sub-layer 110B, and the first planarization sub-layer 110A is located on the side of the second planarization sub-layer 110B close to the substrate 10. In the light-sensing recognition area 30, the thickness of the second planarization sub-layer 110B is h1; in the non-light-sensing recognition area 31, the thickness of the second planarization sub-layer is h2; and h1=h2.

The specific structures and beneficial effects of the first planarization sub-layer 110A and the second planarization sub-layer 110B may be referred to the above-described embodiments, which is not be repeated here.

In this embodiment, as shown in FIG. 6, the second planarization sub-layer 110B in the light-sensing recognition area 30 has the same thickness as that in the non-light-sensing recognition area 31, which is beneficial to eliminate the height difference between the upper surface of the second planarization sub-layer 110B and the light-sensing recognition area 30 and the non-light-sensitive recognition region 31, thereby facilitating ensuring that the surface of the entire second planarization sub-layer 110B is relatively flat, providing a flat surface for manufacturing the light-emission element 12, and avoiding the color shift caused by surface unevenness.

FIG. 7 shows a flow chart of a processing method of a first planarization layer according to embodiments of the present application. Optionally, as shown in FIG. 7, during the manufacturing process of the first planarization layer 11, the first planarization sub-layer 110A may be first formed over the photosensitive element 20, and then the material of the second planarization sub-layer 110B may be uniformly coated on the first planarization sub-layer 110A to ensure that the material uniformly covers the entire surface. During the coating process, because the material of the second planarization sub-layer 110B has a relatively good fluidity, relatively good planarization effect can be achieved to reduce the interference of the step caused by the photosensitive element 20.

Referring to the sectional diagram (A) shown in FIG. 7, after the coating is completed, the second planarization sub-layer 110B may be pre-baked to preliminary cure the material of the second planarization sub-layer 110B, ensure that the second planarization sub-layer 110B does not flow or deform in subsequent processing, and maintain a good planarization effect.

The thicknesses of the first planarization sub-layer 110A and the second planarization sub-layer 110B may be set according to actual needs. For example, the thickness of the first planarization sub-layer 110A may be 1.2 μm, the thickness of the second planarization sub-layer 110B may be 2.2 μm, and under this condition, the thickness of the first planarization layer 11 in the light-sensing recognition area 30 is approximately 3.05 μm to achieve a good planarization effect, which is not limited thereto.

Referring to the sectional diagram (B) shown in FIG. 7, after the formation of the second planarization sub-layer 110B, blanket exposure and development may be performed on the second planarization sub-layer 110B to reduce the overall thickness of the second planarization sub-layer 110B, thereby improving the light transmittance of the second planarization sub-layer 110B, allowing more external light to pass through the first planarization layer 11 and impinge on the photosensitive element 20, thereby improving the photocurrent.

The removed thickness of the second planarization sub-layer 110B and the thickness of the first planarization layer 11 after the second planarization sub-layer 110B is thinned can be set according to actual needs. For example, the blanket exposure and development of the second planarization sub-layer 110B remove thickness of approximately 1.45 μm to improve the light transmittance of the second planarization sub-layer 110B, and after the second planarization sub-layer 110B is thinned, it is ensured that the thickness of the second planarization sub-layer 110B in the light-sensing recognition area 30 is greater than or equal to 0.5 μm to prevent the second planarization sub-layer 110B in the light-sensing recognition area 30 from cracking or peeling to ensure the planarization effect of the second planarization sub-layer 110B. The thickness of the first planarization layer 11 in the light-sensing recognition area 30 is approximately 1.6 μm, and under this condition, in the light-sensing recognition area 30, the light transmittance of the first planarization layer 11 for the light having a wavelength of 400 nm can reach 83%, so that more external light can pass through the first planarization layer 11 and impinge on the photosensitive element 20 to improve the photocurrent, which is not limited thereto.

Referring to the sectional diagram (C) shown in FIG. 7, after the second planarization sub-layer 110B is thinned, the second planarization sub-layer 110B may be patterned by an exposure and development process to form a connection via 50 for achieving electrical connection on the second planarization sub-layer 110B, and may be completely cured by a curing process such as high temperature treatment or ultraviolet irradiation to ensure reliability and stability of the second planarization sub-layer 110B.

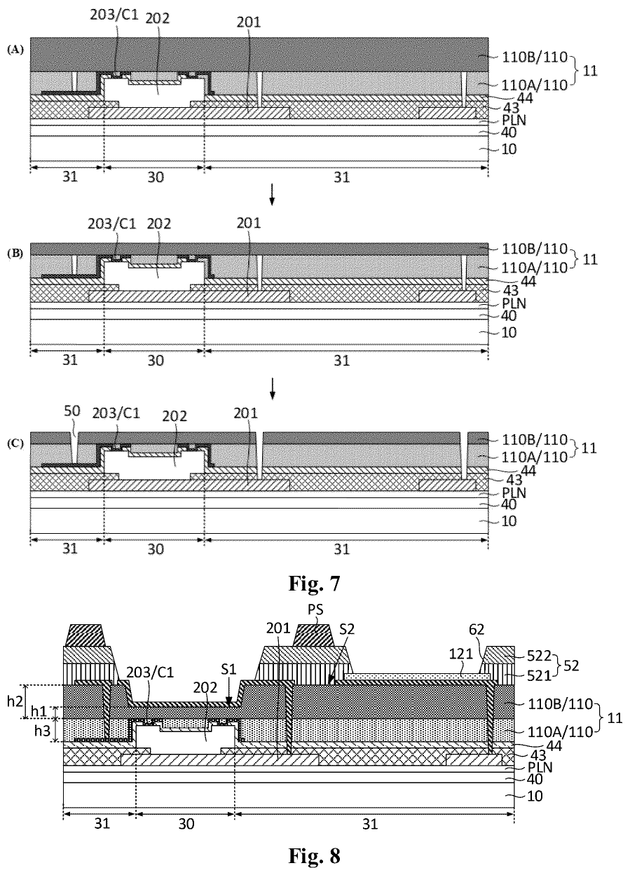

FIG. 8 shows a partial schematic sectional structural view of still another display panel according to embodiments of the present application. Optionally, as shown in FIG. 8, in the light-sensing recognition area 30, the surface of the first planarization layer 11 away from the substrate 10 is a first surface S1. In the non-light-sensing recognition area 31, the surface of the first planarization layer 11 away from the substrate 10 is a second surface S2. The first surface S1 is located at the side of the second surface S2 close to the substrate 10 in a direction perpendicular to the plane where the substrate 10 is located.

As shown in FIG. 8, the upper surface of the first planarization layer 11 in the light-sensing recognition area 30 is the first surface S1, and the upper surface of the first planarization layer 11 in the non-light-sensing recognition area 31 is the second surface S2.

In this embodiment, after the formation of the first planarization layer 11, the light transmittance of the first planarization layer 11 in the light-sensing recognition area 30 may be improved by reducing the thickness of the first planarization layer 11 in the light-sensing recognition area 30.

Specifically, as shown in FIG. 8, in the light-sensing recognition area 30, the first surface S1 of the first planarization layer 11 is relatively close to the substrate 10 to make the thickness of the first planarization layer 11 in the light-sensing recognition area 30 relatively small, thereby improving the light transmittance of the first planarization layer 11 on the photosensitive element 20, enabling more light to pass through the first planarization layer 11 of the light-sensing recognition area 30 to impinge on the photosensitive element 20, increasing the number of photons received by the photosensitive element 20, and improving the photocurrent. Thus, the performance of the photosensitive element 20 can meet the application requirements (e.g., improving the fingerprint recognition efficiency).

In addition, in the non-light-sensing recognition area 31, the second surface S2 of the first planarization layer 11 is relatively far away from the substrate 10 to maintain the thickness of the first planarization layer 11 in the non-light-sensing recognition area 31, thereby maintaining a good planarization effect of the first planarization layer 11 in the non-light-sensing recognition area 31, ensuring that the film layer such as the anode 121 and the light-emission layer 122 above the first planarization layer 11 can be uniformly deposited, which facilitates avoiding the color shift caused by surface unevenness.

Optionally, still referring to FIG. 8, the first planarization layer 11 includes at least two planarization sub-layers 110 that are stacked, and the thickness of the planarization sub-layer 110 farthest from the substrate 10 in the light-sensing recognition area 30 is smaller than that in the non-light-sensing recognition area 31.

As shown in FIG. 8, the first planarization layer 11 is divided into at least two planarization sub-layers 110, and the advantageous effects thereof can be referred to in the aforementioned embodiments, and will not be repeated here.

Further, as shown in FIG. 8, the planarization sub-layer 110 farthest from the substrate 10 refers to the uppermost planarization sub-layer 110 (e.g., the second planarization sub-layer 110B) in the first planarization layer 11.

In this embodiment, the thickness of the planarization sub-layer 110 farthest from the substrate 10 in the light-sensing recognition area 30 (e.g., the thickness h1 of the second planarization sub-layer 110B in the light-sensing recognition area 30) is smaller than the thickness of the planarization sub-layer 110 in the non-light-sensing recognition area 31 (e.g., the thickness h2 of the second planarization sub-layer 110B in the non-light-sensing recognition area 31), so that the thickness of the first planarization layer 11 in the light-sensing recognition area 30 is reduced, thereby improving the light transmittance of the first planarization layer 11 over the photosensitive element 20, and enabling more light to pass through the first planarization layer 11 in the light-sensing recognition area 30 and impinge on the photosensitive element 20, increasing the number of photons received by the photosensitive element 20, and improving the photocurrent. In addition, the thickness of the first planarization layer 11 in the non-light-sensing recognition area 31 is maintained, so that the first planarization layer 11 maintains a good planarization effect in the non-light-sensing recognition area 31, thereby ensuring that the film layer such as the anode 121 and the light-emission layer 122 above the first planarization layer 11 can be uniformly deposited, which facilitates avoiding the color shift caused by surface unevenness.

Optionally, still referring to FIG. 8, the first planarization layer 11 includes a first planarization sub-layer 110A and a second planarization sub-layer 110B that are stacked, and the first planarization sub-layer 110A is located on the side of the second planarization sub-layer 110B close to the substrate 10. In the light-sensing recognition area 30, the thickness of the second planarization sub-layer 110B is h1; in the non-light-sensing recognition area 31, the thickness of the second planarization sub-layer 110B is h2; and 0.2*h2≤h1<h2.

The specific structures and beneficial effects of the first planarization sub-layer 110A and the second planarization sub-layer 110B may be referred to the above-described embodiments, which is not be repeated here.

In this embodiment, as shown in FIG. 8, the thickness h1 of the second planarization sub-layer 110B in the light-sensing recognition area 30 is smaller than the thickness h2 of the second planarization sub-layer 110B in the non-light-sensing recognition area 31 to reduce the thickness of the first planarization layer 11 in the light-sensing recognition area 30, thereby improving the light transmittance of the first planarization layer 11 on the photosensitive element 20, enabling more light to pass through the first planarization layer 11 in the light-sensing recognition area 30 to impinge on the photosensitive element 20, increasing the number of photons received by the photosensitive element 20, and improving the photocurrent. In addition, the thickness of the first planarization layer 11 in the non-light-sensing recognition area 31 is maintained, so that the first planarization layer 11 maintains a good planarization effect in the non-light-sensing recognition area 31, thereby ensuring that the film layer such as the anode 121 and the light-emission layer 122 above the first planarization layer 11 can be uniformly deposited, which facilitates avoiding the color shift caused by surface unevenness.

Further, the thickness h1 of the second planarization sub-layer 110B in the light-sensing recognition area 30 is at least 20% of the thickness h2 of the second planarization sub-layer 110B in the non-light-sensing recognition area 31, the second planarization sub-layer 110B in the light-sensing recognition area 30 can be prevented from cracking or peeling, and the planarization effect of the second planarization sub-layer 110B can be ensured, which is beneficial to providing a relatively flat surface for manufacturing the light-emission element 12, and ensuring that film layers such as the anode 121 and the light-emission layer 122 that are over the first planarization layer 11 can be uniformly deposited, thereby avoiding the color shift caused by surface unevenness.

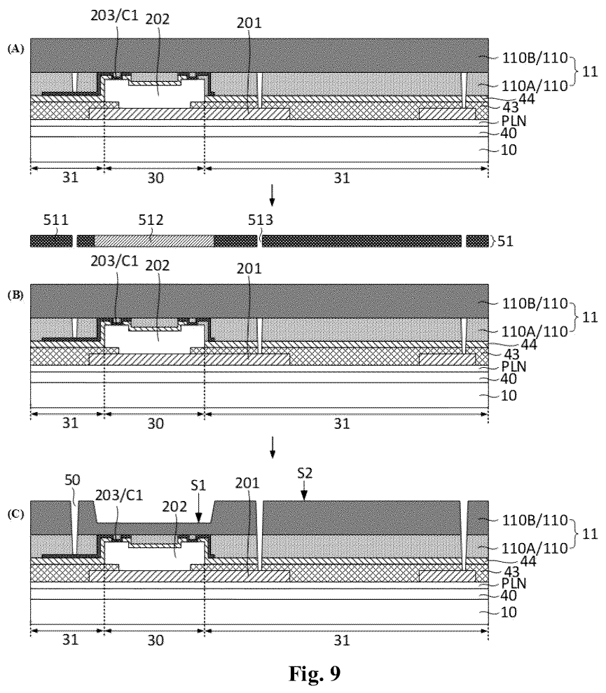

FIG. 9 shows a flow chart of another processing method of the first planarization layer according to embodiments of the present application. Optionally, as shown in FIG. 9, during the manufacturing process of the first planarization layer 11, the first planarization sub-layer 110A may be first formed on the photosensitive element 20, and then the material of the second planarization sub-layer 110B may be uniformly coated on the first planarization sub-layer 110A to ensure that the material uniformly covers the entire surface. During the coating process, because the material of the second planarization sub-layer 110B has a relatively good fluidity, relatively good planarization effect can be achieved to reduce the influence of the step caused by the photosensitive element 20.

Referring to the sectional diagram (A) shown in FIG. 9, after the coating is completed, the second planarization sub-layer 110B may be pre-baked to preliminary cure the material of the second planarization sub-layer 110B, ensure that the second planarization sub-layer 110B does not flow or deform in subsequent processing, and maintain a good planarization effect.

The thicknesses of the first planarization sub-layer 110A and the second planarization sub-layer 110B may be set according to actual needs. For example, the thickness of the first planarization sub-layer 110A may be 1.2 μm, the thickness of the second planarization sub-layer 110B may be 2.2 μm, and under this condition, the thickness of the first planarization layer 11 in the light-sensing recognition area 30 is approximately 3.05 μm to achieve a good planarization effect, which is not limited thereto.

Referring to the sectional diagrams (B) and (C) shown in FIG. 9, after the formation of the second planarization sub-layer 110B, the exposure and development operations may be performed on the second planarization layer 110B using a multi-hue photomask 51 including a first light-blocking portion 511 and a first exposure portion 512 corresponding to the light-sensing recognition area 30, and the light transmittance of the first exposure portion 512 is greater than the light transmittance of the first light-blocking portion 511. In this case, the etching degree of the second planarization sub-layer 110B corresponding to the first light-blocking portion 512 is greater than that corresponding to the first light-blocking portion 511, thereby reducing the thickness of the second planarization sub-layer 110B only in the light-sensing planarization area 30, increasing the light transmittance of the first planarization layer 11 on the photosensitive element 20, and improving the photocurrent. In addition, the thickness of the second planarization sub-layer 110B in the non-light-sensing recognition area 31 is maintained, so that the second planarization sub-layer 110B maintains a good planarization effect in the non-light-sensing recognition area 31, and the color shift caused by surface unevenness is avoided.

Further, the second planarization sub-layer 110B may be completely cured by a curing process, such as high temperature treatment or ultraviolet irradiation, to ensure the reliability and stability of the second planarization sub-layer 110B.

Optionally, the multi-hue photomask 51 may be a Halftone Mask (HTM) or a Graytone Mask (GTM), but is not limited thereto.

Further, the removed thickness of the second planarization sub-layer 110B in the light-sensing recognition area 30 and the thickness of the first planarization layer 11 in the light-sensing recognition area 30 after the second planarization sub-layer 110B is thinned may be set according to actual needs. For example, the thickness of the second planarization sub-layer 110B in the light-sensing recognition area 30 is removed by approximately 1.45 μm to increase the light transmittance of the second planarization sub-layer 110B in the light-sensing recognition area 30. After the second planarization sub-layer 110B in the light-sensing recognition area 30 is thinned, it can be ensured that the thickness of the second planarization sub-layer 110B in the light-sensing recognition area 30 is greater than or equal to 0.5 μm, thereby preventing the second planarization sub-layer 110B in the light-sensing recognition area 30 from cracking or peeling and ensuring the planarization effect of the second planarization sub-layer 110B. The thickness of the first planarization layer 11 in the light-sensing recognition area 30 is approximately 1.6 μm, and under this condition, in the light-sensing recognition area 30, the light transmittance of the first planarization layer 11 for the light having a wavelength of 400 nm can reach 83%, so that more external light can pass through the first planarization layer 11 in the light-sensing recognition area 30 and impinge on the photosensitive element 20, thereby improving the photocurrent, which is not limited thereto.

Optionally, still referring to the sectional diagrams (B) and (C) shown in FIG. 9, the multi-hue photomask 51 further includes a second exposure portion 513 corresponding to the connection via 50, the light transmittance of the second exposure portion 513 is greater than that of the first exposure portion 512. When exposure and development are performed on the second planarization sub-layer 110B using multi-hue photomask 51, the etched degree of the second planarization sub-layer 110B corresponding to the second exposure region 513 is greater than that corresponding to the first exposure region 512, so that the connection via 50 for electrical connection is simultaneously formed on the second planarization sub-layer 110B, which facilitates shortening process cycle time and reducing manufacturing cost.

Further, when exposure and development are performed on the second planarization sub-layer 110B using multi-hue photomask 51, the light transmittance and the exposure dose of the first light-blocking portion 511, the first exposure portion 512, and the second exposure portion 513 can be set according to actual needs. For example, when the light transmittance of the first light-blocking portion 511 is 0, the light transmittance of the first exposure portion 512 is in a range of 15% to 30%, and the light transmittance of the second exposure portion 513 is 100%, the second exposure portion 513 may have a hollow structure, which is not limited thereto and is not particularly limited in embodiments of the present application.

Exemplarily, taking the light transmittance of the first exposure portion 512 being 24% as an example for description, when the exposure and development operations are performed on the second planarization sub-layer 110B using the multi-hue photomask 51, if the exposure dose is 200 Dose and the exposure dose passing through the first exposure portion 512 is 48 Dose, the thickness of the second planarization sub-layer 110B can be removed by 1.45 μm in the light-sensing recognition area 30.

It can be understood that when the exposure and development operations are performed on the second planarization sub-layer 110B using the multi-hue photomask 51, the second planarization sub-layer 110B receives an exposure dose of 1 Dose, and a thickness of approximately 0.03 μm may be removed. Therefore, in other embodiments, the light transmittance and the exposure dose of each region of the multi-hue photomask 51 can be calculated and determined according to the thicknesses of the second planarization sub-layer 110B to be removed in the respective regions, which is not specifically limited in embodiments of the present application.

Optionally, still referring to FIG. 8, the first planarization layer 11 includes a first planarization sub-layer 110A and a second planarization sub-layer 110B that are stacked, and the first planarization sub-layer 110A is located on the side of the second planarization sub-layer 110B close to the substrate 10. The thickness h1 of the second planarization sub-layer 110B in the light-sensing recognition area 30 is less than or equal to the thickness h3 of the first planarization sub-layer 110A in the non-light-sensing recognition area 31.

The specific structures and beneficial effects of the first planarization sub-layer 110A and the second planarization sub-layer 110B may be referred to the above-described embodiments, which is not be repeated here.

In this embodiment, as shown in FIG. 8, the thickness h1 of the second planarization sub-layer 110B in the light-sensing recognition area 30 is less than or equal to the thickness h3 of the first planarization sub-layer 110A in the non-light-sensing recognition area 31 to reduce the thickness of the first planarization layer 11 in the light-sensing recognition area 30, thereby improving the light transmittance of the first planarization layer 11 on the photosensitive element 20, enabling more light passing through the first planarization layer 11 in the light-sensing recognition area 30 to impinge on the photosensitive element 20, increasing the number of photons received by the photosensitive element 20, and improving the photocurrent. In addition, the first planarization sub-layer 110A has a sufficient thickness in the non-light-sensing recognition area 31, so that the first planarization sub-layer 110A has a good planarization effect in the non-light-sensing recognition area 31, and the color shift caused by surface unevenness is avoided.

It should be noted that the specific thickness of the second planarization sub-layer 110B in the light-sensing recognition area 30 may be set according to actual needs. For example, the thickness of the second planarization sub-layer 110B in the light-sensing recognition area 30 may be in a range of 0.5 μm to 2.2 μm (e.g., 0.75 μm), thereby improving the light transmittance of the second planarization sub-layer 110B in the light-sensing recognition area 30 while the planarization effect is ensured, which is not limited thereto and is not specifically limited in embodiments of the present application.

Optionally, still referring to FIGS. 6 and 8, the material of the first planarization layer 11 includes at least one of PI or PMMA. In the light-sensing recognition area 30, the thickness of the first planarization layer 11 is less than or equal to 3.05 μm and greater than or equal to 1.35 μm.

In this embodiment, by replacing the material of the first planarization layer 11 with a material having a relatively high light transmittance (e.g., at least one of PI or PMMA), the light transmittance of the first planarization layer 11 is improved, so that more light can pass through the first planarization layer 11 and impinge on the photosensitive element 20, the number of photons received by the photosensitive element 20 is increased, and the photocurrent is improved.

Meanwhile, after the formation of the first planarization layer 11, the light transmittance of the first planarization layer 11 may be further improved by reducing the thickness of the first planarization layer 11.

Specifically, as shown in FIGS. 6 and 8, the thickness of at least a portion of the first planarization layer 11 within the light-sensing recognition area 30 is reduced, so that the thickness of the first planarization layer 11 in the light-sensing recognition area 30 is less than or equal to 3.05 μm and greater than or equal to 1.35 μm, thereby improving the light transmittance of the first planarization layer 11 in the light-sensing recognition area 30 while the planarization effect is ensured, enabling more light passing through the first planarization layer 11 to impinge on the photosensitive element 20, increasing the number of photons received by the photosensitive element 20, and increasing the photocurrent. Thus, the performance of the photosensitive element 20 can meet the application requirements (e.g., improving the fingerprint recognition efficiency).

Optionally, still referring to FIGS. 2, 5, and 6, the display panel provided in embodiments of the present application further includes a pixel definition layer 52 located on the side of the first planarization layer 11 away from the substrate 10. The pixel definition layer 52 includes first openings 61, and the first opening 61 at least partially overlaps the light-sensing recognition area 30 in a direction perpendicular to the plane where the substrate 10 is located.

Specifically, as shown in FIGS. 2, 5, and 6, a pixel definition layer 52 is disposed on the first planarization layer 11 and the anode 121, and the pixel definition layer 52 are provided with second openings 62, and the light-emission layer 122 may be formed in the second opening 62 of the pixel definition layer 52.

The pixel definition layer 52 is for limiting the boundary of each pixel, and the pixel definition layer 52 isolates the respective light-emission elements 12 from each other, which can effectively prevent current leakage and optical crosstalk between adjacent two of the pixels, thereby improving the display quality.

Optionally, still referring to FIGS. 2, 5, and 6, the pixel definition layer 52 may include a first pixel definition layer 521 and a second pixel definition layer 522 that are stacked, and the second pixel definition layer 522 is disposed on the side of the first pixel definition layer 521 away from the substrate 10. The first pixel definition layer 521 may be provided as a black pixel definition layer to absorb light between adjacent two of the pixels, thereby preventing optical crosstalk therebetween.

In this embodiment, as shown in FIGS. 2, 5 and 6, the pixel definition layer 52 is provided with the first opening 61, and the first opening 61 at least partially overlaps the photosensitive element 20 in the direction perpendicular to the plane where the substrate 10 is located, which can reduce the light blocking caused by the pixel definition layer 52 in the light-sensing recognition area 30, so that more light can pass through the pixel definition layer 52 in the light-sensing recognition area 30 to impinge on the photosensitive element 20, increase the number of photons received by the photosensitive element 20, and improve the photocurrent. Thus, the performance of the photosensitive element 20 can meet the application requirements (e.g., improving the fingerprint recognition efficiency).

Optionally, as shown in FIGS. 2, 5 and 6, the first opening 61 covers the photosensitive element 20 in a direction perpendicular to the plane where the substrate 10 is located, which can further reduce the light blocking caused by the pixel definition layer 52 in the light-sensing recognition area 30, so that more light can pass through the pixel definition layer 52 in the light-sensing recognition area 30 and impinge on the photosensitive element 20, thereby increasing the photocurrent.

Optionally, still referring to FIG. 2, the cathode 123 is located inside the first opening 61, and is electrically connected to the first electrode 201.

The cathode 123 provides a low-voltage signal to the first electrode 201 of the photosensitive element 20 through the first opening 61, without additional wiring or complicated circuit connection, which can simplify the structure of the display panel, and facilitate simplifying the manufacturing process and reducing the production cost.

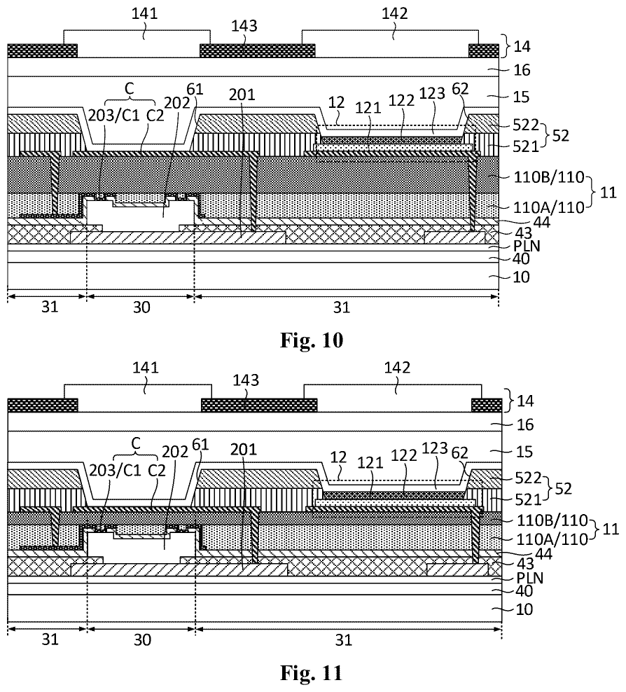

FIG. 10 shows a partial schematic sectional structural view of still another display panel according to embodiments of the present application; and FIG. 11 shows a partial schematic sectional structural view of still another display panel according to embodiments of the present application. As shown in FIGS. 10 and 11, the display panel further includes a color film layer 14 located on the side of the light-emission element 12 away from the substrate 10. The color film layer 14 includes a first light-transmitting portion 141, and the first light-transmitting portion 141 at least partially overlaps the first opening 61 in the direction perpendicular to the plane where the substrate 10 is located.

Specifically, the display panel includes multiple metal film layers, and ambient light may be reflected when impinges on the display panel, which can affect the user's experience. Therefore, a polarizer is usually disposed at the side of the display panel where the light-emission surface is located, thereby eliminating light reflection through the polarizer. However, adding the polarizer requires additional process steps, and increases the thickness of the encapsulated display panel is relatively large, which is not beneficial to the light and thin design.

Based on the above-described technical problems, in this embodiment, as shown in FIGS. 10 and 11, the color film layer 14 is disposed at the side of the display panel where the light-emission surface is located, and the color film layer 14 includes color resists 142 corresponding to the light-emission elements 12, and a black matrix 143 corresponding to gaps between adjacent two of the light-emission elements 12. The black matrix 143 can block the reflected light from being emitted, and the color resist 142 can filter the light emitted by the light-emission element 12 to make the chromaticity of the light emitted by the light-emission element 12 purer when emitted from the display panel. In this way, the color film layer 14 replaces the polarizer to achieve the effect of eliminating light reflection without a polarizer, thereby reducing manufacturing process steps and the thickness of the display panel.

Further, as shown in FIGS. 10 and 11, the color film layer 14 may further include a first light-transmitting portion 141, and the first light-transmitting portion 141 at least partially overlaps the first opening 61 in a direction perpendicular to the plane where the substrate 10 is located. In this case, the first light-transmitting portion 141 overlaps the photosensitive element 20, which can reduce the light blocking caused by the color film layer 14 in the light-sensing recognition area 30, so that more light can pass through color film layer 14 in the light-sensing recognition area 30 to impinge on the photosensitive element 20, increase the number of photons received by the photosensitive element 20, and improve the photocurrent. Thus, the performance of the photosensitive element 20 can meet the application requirements (e.g., improving the fingerprint recognition efficiency).

Optionally, as shown in FIGS. 10 and 11, the first light-transmitting portion 141 covers the photosensitive element 20 in a direction perpendicular to the plane where the substrate 10 is located. Additionally or alternatively, the first light-transmitting portion 141 covers the first opening 61, which can further reduce the light blocking caused by the color film layer 14 in the light-sensing recognition area 30, so that more light can pass through the color film layer 14 in the light-sensing recognition area 30 and impinge on the photosensitive element 20, thereby improving the photocurrent.

It can be understood that in the direction perpendicular to the plane where the substrate is located, there is an overlapping area among the first light-transmitting portion 141, the first opening 61, and the photosensitive element 20, which facilitates reducing the light 10 blocking caused by the pixel definition layer 52 and the color film layer 14 in the light-sensing recognition area 30, so that more light can pass through the pixel definition layer 52 and the color film layer 14 in the light-sensing recognition area 30 and impinge on the photosensitive element 20, thereby improving the photocurrent.

Optionally, the first light-transmitting portion 141 may be made of a light-filtering material, so that the first light-transmitting portion 141 can filter out stray ambient light and reduce interference from ambient light on fingerprint recognition, thereby improving the signal-to-noise ratio and reducing the false rejection rate of fingerprint recognition.

Exemplarily, during fingerprint recognition, if an infrared light source is used for fingerprint imaging, the material of the first light-transmitting portion 141 can be selected to make the first light-transmitting portion 141 block all light except infrared, allowing only infrared light to pass through, so that the interference from ambient light can be effectively reduced to ensure that the photosensitive element 20 mainly receives infrared light reflected from the finger, thereby improving the signal-to-noise ratio and reducing the false rejection rate of fingerprint recognition, which is not limited thereto.

Optionally, still referring to FIGS. 10 and 11, the display panel further includes a thin film encapsulation layer 15, and the thin film encapsulation layer 15 is located on the side of the light-emission element 12 away from the substrate 10, and may be located between the light-emission element 12 and the color film layer 14 specifically.

The thin film encapsulation layer 15 can completely cover the light-emission element 12 to play a role of sealing and protecting the light-emission element 12.

Further, the thin film encapsulation layer 15 may include at least an inorganic encapsulation layer and an organic encapsulation layer that are stacked, and may have advantages such as lightness, thinness, and flexibility while serving to insulate water vapor, which is not limited thereto.

Optionally, still referring to FIGS. 10 and 11, the display panel further includes a touch function layer 16, and the touch function layer 16 is for achieving the touch function of the display panel, wherein the touch function layer 16 may be located at the side of the light-emission element 12 away from the substrate 10, and specifically between the thin film encapsulation layer 15 and the color film layer 14, which is not specifically limited in embodiments of the present application.

Based on the same inventive concept, embodiments of the present application further provides a display panel, and as shown in FIGS. 6 and 8, the display panel provided in embodiments of the present application includes:
a substrate 10;
a photosensitive element 20 disposed at the side of the substrate 10, wherein an area where the photosensitive element 20 is located is a light-sensing recognition area 30 located in a display area AA of the display panel;
a first planarization layer 11 disposed at the side of the photosensitive element 20 away from the substrate 10; and
a light-emission element 12 disposed at the side of the first planarization layer 11 away from the base substrate 10,

In the light-sensing recognition area 30, the thickness H1 of the first planarization layer 11 is less than or equal to 3.05 μm and greater than or equal to 1.35 μm.

The explanations of structures and terms that are the same or corresponding to the above embodiments are not repeated here.

In this embodiment, after the formation of the first planarization layer 11, the light transmittance of the first planarization layer 11 may be improved by reducing the thickness of the first planarization layer 11.

Specifically, as shown in FIGS. 6 and 8, the thickness of at least a portion of the first planarization layer 11 within the photosensitive recognition region 30 may be reduced, so that the thickness H1 of the first planarization layer 11 in the light-sensing recognition area 30 is less than or equal to 3.05 μm, thereby improving the light transmittance of the first planarization layer 11 in the light-sensing recognition area 30, enabling more light to pass through the first planarization layer 11 to impinge on the photosensitive element 20, and improving the photocurrent. Thus, the performance of the photosensitive element 20 can meet the application requirements (e.g., improving the fingerprint recognition efficiency).

Meanwhile, the thickness H1 of the first planarization layer 11 in the light-sensing recognition area 30 is set to be greater than or equal to 1.35 μm, which can ensure that the first planarization layer 11 can still completely cover the photosensitive element 20 even in the case of process error, can provide effective protection for the photosensitive element 20 while ensuring the planarization effect, and is beneficial to avoiding the photosensitive element 20 being damaged in the subsequent process, thereby improving the reliability and stability of the photosensitive element 20.

It should be noted that the specific thickness of the first planarization layer 11 in the light-sensing recognition area 30 may be set according to actual needs. For example, as shown in FIGS. 6 and 8, the thickness H1 of the first planarization layer 11 in the light-sensing recognition area 30 may be 1.6 μm to improve the light transmittance of the first planarization layer 11 in the light-sensing recognition area 30 while the planarization effect is ensured, which is not limited thereto and is not specifically limited in embodiments of the present application.

Optionally, as shown in FIG. 6, the non-light sensing recognition area 31 is an area in the display area except the light-sensing recognition area 30. In the light-sensing recognition area 30, the surface of the first planarization layer 11 away from the substrate 10 is the first surface S1. In the non-light-sensing recognition area 31, the surface of the first planarization layer 11 away from the substrate 10 is the second surface S2. The distance between the first surface S1 and the second surface S2 is less than or equal to 0.5 μm in a direction perpendicular to the plane where the substrate 10 is located.

In this embodiment, as shown in FIG. 6, the height difference between the first surface S1 of the first planarization layer 11 in the light-sensing recognition area 30 and the second surface S2 of the first planarization layer 11 in the non-light-sensing recognition area 31 is less than or equal to 0.5 μm, so that the height difference between the first surface S1 of the first planarization layer 11 in the light-sensing recognition area 30 and the second surface S2 of the first planarization layer 11 in the non-light-sensing recognition area 31 is relatively small, which is beneficial to eliminating the step caused by the photosensitive element 20, providing a relatively flat surface for manufacturing the light-emission element 12, ensuring that film layers such as the anode 121 and the light-emission layer 122 can be uniformly deposited, thereby avoiding the color shift caused by surface unevenness.

Optionally, as shown in FIG. 8, the non-light sensing recognition area 31 is an area in the display area except the light-sensing recognition area 30. In the light-sensing recognition area 30, the surface of the first planarization layer 11 away from the substrate 10 is the first surface S1. In the non-light-sensing recognition area 31, the surface of the first planarization layer 11 away from the substrate 10 is the second surface S2. The first surface S1 is located at the side of the second surface S2 close to the substrate 10 in a direction perpendicular to the plane where the substrate 10 is located.

In this embodiment, after the formation of the first planarization layer 11, the light transmittance of the first planarization layer 11 in the light-sensing recognition area 30 may be improved by reducing the thickness of the first planarization layer 11 in the light-sensing recognition area 30.

Specifically, as shown in FIG. 8, in the light-sensing recognition area 30, the first surface S1 of the first planarization layer 11 is relatively close to the substrate 10 to make the thickness of the first planarization layer 11 in the light-sensing recognition area 30 relatively small, thereby improving the light transmittance of the first planarization layer 11 on the photosensitive element 20, enabling more light to pass through the first planarization layer 11 of the light-sensing recognition area 30 to impinge on the photosensitive element 20, increasing the number of photons received by the photosensitive element 20, and improving the photocurrent. Thus, the performance of the photosensitive element 20 can meet the application requirements (e.g., improving the fingerprint recognition efficiency).

In addition, in the non-light-sensing recognition area 31, the second surface S2 of the first planarization layer 11 is relatively far away from the substrate 10 to maintain the thickness of the first planarization layer 11 in the non-light-sensing recognition area 31, thereby maintaining a good planarization effect of the first planarization layer 11 in the non-light-sensing recognition area 31, ensuring that the film layer such as the anode 121 and the light-emission layer 122 above the first planarization layer 11 can be uniformly deposited, which facilitates avoiding the color shift caused by surface unevenness.

Optionally, still referring to FIGS. 5 and 6, the display panel further includes support posts PS located on the side of the pixel definition layer 52 away from the substrate 10. The support pillar PS is located on the pixel definition layer PDL between adjacent two of the pixels, and can be used to support a structure such as a mask plate, an encapsulation layer, or a cover plate to prevent deformation or damage of a device in the display panel due to an external force or pressure.

Optionally, still referring to FIGS. 2 and 5-11, the display panel further includes a buffer layer 43 located on the side of the first electrode 201 away from the substrate 10 in a direction perpendicular to the plane where the substrate 10 is located.

For example, as shown in FIGS. 2 and 5-11, the buffer layer 43 is located between the first electrode 201 and the PIN structure 202, and the PIN structure 202 forms an electrical connection with the first electrode 201 through an opening on the buffer layer 43.

The buffer layer 43 can play the role of reducing the step, and additionally, the buffer layer 43 can further play the role of shock prevention, buffer, and isolation.

Optionally, still referring to FIGS. 2 and 5-11, the display panel further includes a passivation layer 44 located on the side of the PIN structure 202 away from the substrate 10 in the direction perpendicular to the plane where the substrate 10 is located.

For example, as shown in FIGS. 2 and 5-11, the passivation layer 44 is located between the second electrode 203 and the PIN structure 202, and the second electrode 203 forms an electrical connection with the PIN structure 202 through an opening on the passivation layer 44.

The passivation layer 44 can prevent the chemical reactions between the surface of the PIN structure 202 and the external environment to reduce the formation of surface states, thereby improving the performance and service life of devices.

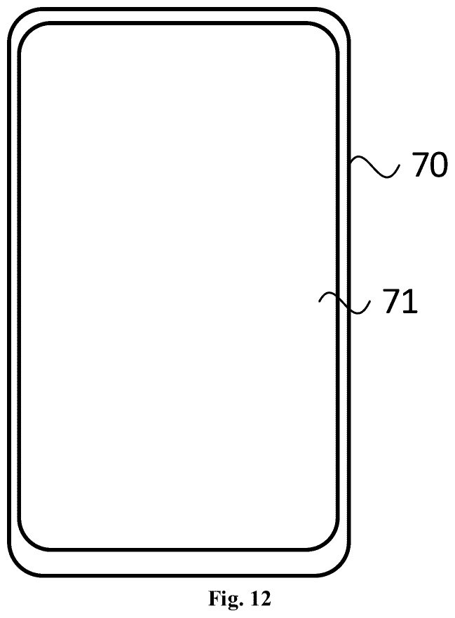

Based on the same inventive concept, embodiments of the present application further provide a display apparatus. FIG. 12 shows a schematic structural view of a display apparatus according to embodiments of the present application. As shown in FIG. 12, the display apparatus 70 includes the display panel 71 described in any one of the embodiments of the present application. Therefore, the display apparatus 70 provided in embodiments of the present application has the technical effect of the technical solution in any one of the above embodiments, and the explanations of structures and terms that are the same or corresponding to the above embodiments are not repeated here.

The display apparatus 70 provided in embodiments of the present application may be a mobile phone shown in FIG. 12, and may also be any electronic product with a display function, including but not limited to the following categories: televisions, notebook computers, desktop displays, tablet computers, digital cameras, smart bracelets, smart glasses, vehicle-mounted displays, medical equipment, industrial control equipment, touch interactive terminals, and the like, which are not particularly limited in the embodiment of the present application.

It should be understood that the various forms of processes shown above can be used to reorder, add, or delete steps. For example, the steps described in the present application may be executed in parallel, sequentially, or in different orders, as long as the desired results of the technical solution of the present application can be achieved, which is not limited in the present application.

The above specific embodiments do not constitute a limitation to the protection scope of the present application. It should be understood by those skilled in the art that various modifications, combinations, sub-combinations, and substitutions may be made according to the design requirements and other factors. Any modification, equivalent replacement and improvement made within the spirit and principle of the present application shall be included in the protection scope of the present application.

What is claimed is:

1. A display panel, comprising:
a substrate;
a photosensitive element located at a side of the substrate, wherein an area where the photosensitive element is located is a light-sensing recognition area, and the light-sensing recognition area is located in a display area of the display panel;
a first planarization layer located on a side of the photosensitive element away from the substrate; and
a light-emission element located on a side of the first planarization layer away from the substrate,
wherein in the light-sensing recognition area, a light transmittance of the first planarization layer is greater than or equal to 67%.

2. The display panel according to claim 1, wherein
a light transmittance of the first planarization layer for a first-wavelength light is greater than or equal to 67%; and
a wavelength of the first-wavelength light is 21, where 380 nm≤21≤435 nm.

3. The display panel according to claim 1, wherein
a material of the first planarization layer comprises at least one of polyimide or polymethyl methacrylate.

4. The display panel according to claim 2, wherein
the first planarization layer comprises at least two planarization sub-layers; and
in the planarization sub-layers, a material of the planarization sub-layer farthest from the substrate is different from a material of the other planarization sub-layers.

5. The display panel according to claim 4, wherein
the light transmittance of the planarization sub-layer farthest from the substrate is greater than the light transmittance of the other planarization sub-layers.

6. The display panel according to claim 2, wherein
the first planarization layer comprises at least two planarization sub-layers; and
the at least two planarization sub-layers comprise a first planarization sub-layer and a second planarization sub-layer, and the first planarization sub-layer is located on a side of the second planarization sub-layer close to the substrate; and
a thickness of the second planarization sub-layer is greater than a thickness of the first planarization sub-layer.

7. The display panel according to claim 2, wherein
an area in the display area except the light-sensing recognition area is a non-light-sensing recognition area; and
a thickness of the first planarization layer in the light-sensing recognition area is smaller than a thickness of the first planarization layer in the non-light-sensing recognition area.

8. The display panel according to claim 7, wherein
in the light-sensing recognition area, the thickness of the first planarization layer is less than or equal to 3.05 μm and greater than or equal to 1.35 μm.

9. The display panel according to claim 8, wherein
the first planarization layer comprises a first planarization sub-layer and a second planarization sub-layer, and the first planarization sub-layer is located on a side of the second planarization sub-layer close to the substrate; and
in the light-sensing recognition area, a thickness of the second planarization sub-layer is greater than or equal to 0.5 μm.

10. The display panel according to claim 7, wherein
in the light-sensing recognition area, a surface of the first planarization layer away from the substrate is a first surface;
in the non-light-sensing recognition area, a surface of the first planarization layer away from the substrate is a second surface; and
a distance between the first surface and the second surface is less than or equal to 0.5 μm in a direction perpendicular to a plane where the substrate is located.

11. The display panel according to claim 10, wherein
the first planarization layer comprises a first planarization sub-layer and a second planarization sub-layer, and the first planarization sub-layer is located on a side of the second planarization sub-layer close to the substrate;
in the light-sensing recognition area, a thickness of the second planarization sub-layer is h1; and
in the non-light-sensing recognition area, a thickness of the second planarization sub-layer is h2, where h1=h2.

12. The display panel according to claim 7, wherein
an area in the display area except the light-sensing recognition area is a non-light-sensing recognition area; and
in the light-sensing recognition area, a surface of the first planarization layer away from the substrate is a first surface;
in the non-light-sensing recognition area, a surface of the first planarization layer away from the substrate is a second surface; and
the first surface is located on a side of the second surface close to the substrate in a direction perpendicular to a plane where the substrate is located.

13. The display panel according to claim 12, wherein
the first planarization layer comprises at least two planarization sub-layers that are stacked; and
a thickness of the planarization sub-layer farthest from the substrate in the light-sensing recognition area is less than a thickness of the planarization sub-layer farthest from the substrate in the non-light-sensing recognition area.

14. The display panel according to claim 12, wherein
the first planarization layer comprises a first planarization sub-layer and a second planarization sub-layer that are stacked, and the first planarization sub-layer is located on a side of the second planarization sub-layer close to the substrate;
in the light-sensing recognition area, a thickness of the second planarization sub-layer is h1; and
in the non-light-sensing recognition area, a thickness of the second planarization sub-layer is h2, where 0.2*h2≤h1<h2.

15. The display panel according to claim 7, wherein
the first planarization layer comprises a first planarization sub-layer and a second planarization sub-layer that are stacked, and the first planarization sub-layer is located on a side of the second planarization sub-layer close to the substrate; and
a thickness of the second planarization sub-layer in the light-sensing recognition area is less than or equal to a thickness of the first planarization sub-layer in the non-light-sensing recognition area.

16. The display panel according to claim 1, wherein
a material of the first planarization layer comprises at least one of polyimide or polymethyl methacrylate; and
in the light-sensing recognition area, a thickness of the first planarization layer is less than or equal to 3.05 μm and greater than or equal to 1.35 μm.

17. A display panel, comprising:
a substrate;
a photosensitive element located at a side of the substrate, wherein an area where the photosensitive element is located is a light-sensing recognition area, and the light-sensing recognition area is located in a display area of the display panel;
a first planarization layer located on a side of the photosensitive element away from the substrate; and
a light-emission element located on a side of the first planarization layer away from the substrate,
wherein in the light-sensing recognition area, a thickness of the first planarization layer is less than or equal to 3.05 μm and greater than or equal to 1.35 μm.

18. The display panel according to claim 17, wherein
an area in the display area except the light-sensing recognition area is a non-light-sensing recognition area; and
in the light-sensing recognition area, a surface of the first planarization layer away from the substrate is a first surface;
in the non-light-sensing recognition area, a surface of the first planarization layer away from the substrate is a second surface; and
a distance between the first surface and the second surface is less than or equal to 0.5 μm in a direction perpendicular to a plane where the substrate is located.

19. The display panel according to claim 17, wherein
an area in the display area except the light-sensing recognition area is a non-light-sensing recognition area; and
in the light-sensing recognition area, a surface of the first planarization layer away from the substrate is a first surface;
in the non-light-sensing recognition area, a surface of the first planarization layer away from the substrate is a second surface; and
the first surface is located on a side of the second surface close to the substrate in a direction perpendicular to a plane where the substrate is located.

20. A display apparatus comprising
a display panel comprising:
a substrate;
a photosensitive element located at a side of the substrate, wherein an area where the photosensitive element is located is a light-sensing recognition area, and the light-sensing recognition area is located in a display area of the display panel;
a first planarization layer located on a side of the photosensitive element away from the substrate; and
a light-emission element located on a side of the first planarization layer away from the substrate,
wherein in the light-sensing recognition area, a light transmittance of the first planarization layer is greater than or equal to 67%.
